(19) United States
(12) Patent Application Publication
(10) Pub. No.: US 2003/0048111 A1
(43) Pub. Date: Mar. 13, 2003

(54) Test Fixture Comprising Drilled and Etched Pin holes and Related Methods.

(76) Inventor: Dale J. Lubitz, Chaska, MN (US)

Correspondence Address: Curtis Brueske, Honeywell International Inc., P. O. Box 2245, 101 Columbia Road, Morristown, NJ, 07962, US

(21) Appl. No.: 09/952,685

(22) Filed: Sep. 13, 2001

(51) Int. Cl. G01R 31/02

(52) U.S. Cl. 324/761

(57) ABSTRACT

A test fixture includes a pin support plate that have been subjected to an etching process to clean up any pin receiving holes prior to the insertion of test pins into the plate. Cleaning up of the pin receiving holes includes at least partially removing plate materials left in the pin receiving holes after the pin receiving hole formation process.

### FIELD OF THE INVENTION

The field of the invention is electrical test fixture fabrication.

### BACKGROUND OF THE INVENTION

In testing printed wiring boards and other electrical devices, it is not uncommon to use a test fixture to act as the interface between the device to be tested and any cabling or equipment used in the test. Such fixtures often comprise a plate having several holes drilled in it for receiving test pins that are to be placed in electrical contact with the device being tested. It is desirable that such test fixtures be manufacturable with a minimal amount of effort, and operate with a degree of accuracy.

### SUMMARY OF THE INVENTION

The present invention is directed to test fixtures that include pin support plates that have been subjected to an etching process to clean up any pin receiving holes prior to the insertion of test pins into the plate. It is contemplated that subjecting the pin support plate to an etching process will render the pin receiving holes better suited for receiving test pins such that the pins can be more easily inserted into the holes and allow movement of the pins within the holes. It is contemplated that pin movement into and within the holes results, at least in part, from the removal of plate material which remains in the pin receiving holes after the holes are drilled.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a view of a test fixture embodying the invention

FIG. 2 is a diagram of a first method embodying the invention.

FIG. 3 is a diagram of a second method embodying the invention.

FIG. 4A is a first photograph of a test fixture prior to etching.

FIG. 4B is a second photograph of a test fixture prior to etching.

FIG. 4C is a third photograph of a test fixture prior to etching.

FIG. 4D is a fourth photograph of a test fixture prior to etching.

FIG. 5A is a photograph of a test fixture after etching.

FIG. 5B is a photograph of a test fixture after etching.

FIG. 5C is a photograph of a test fixture after etching.

### DETAILED DESCRIPTION

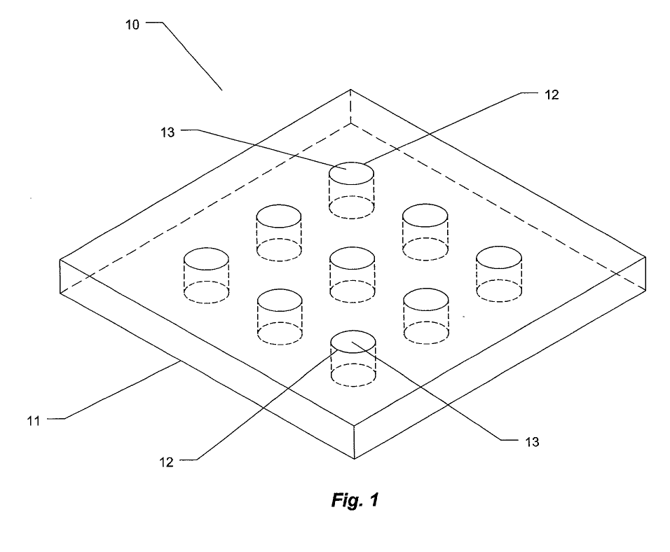

Referring first to FIGS. 1, a test fixture 10 comprises a pin support plate 11, pin receiving holes 12, and test pins 13. Although plate 11 may be composed of any material or combination of materials, it is currently preferred that plat 11 be composed of G10 epoxy glass material. Similarly, pins 13 may be composed of any suitably conductive material or combination of materials, but it is currently preferred that pins 13 be composed of beryllium copper.

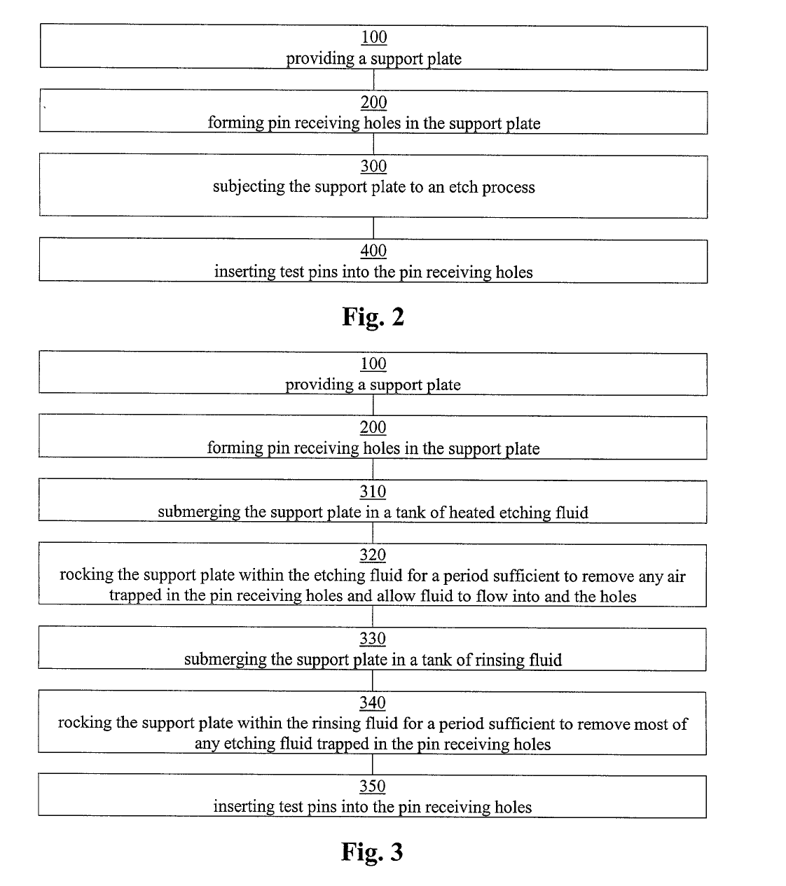

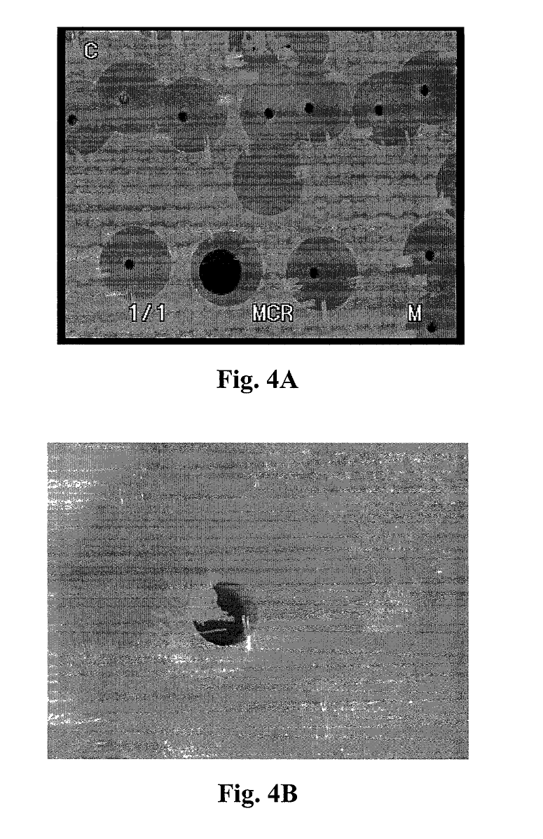

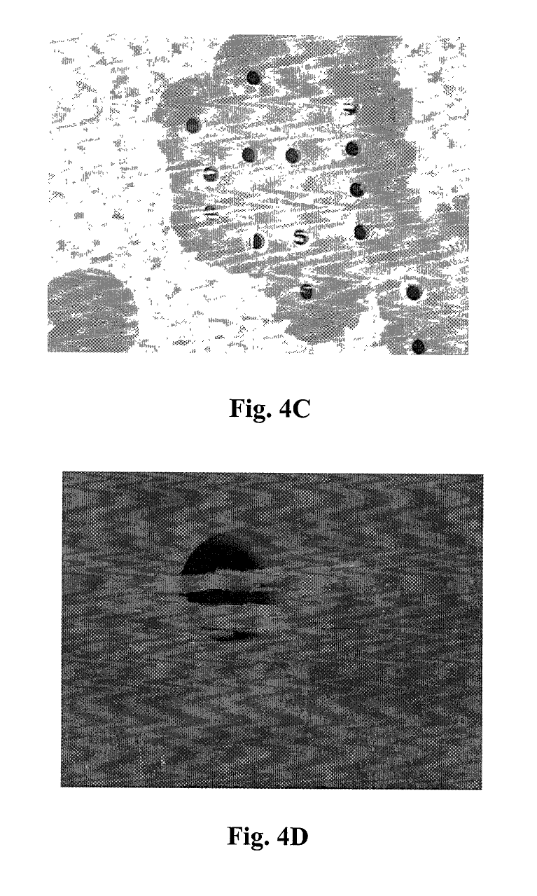

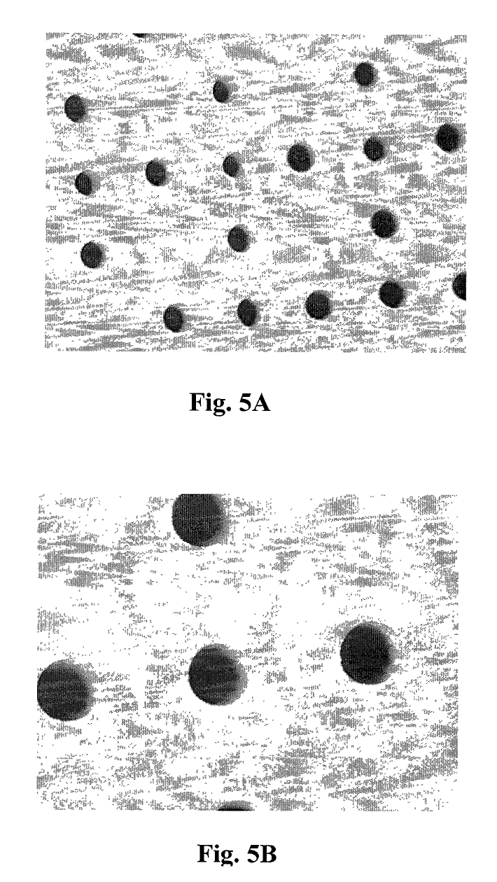

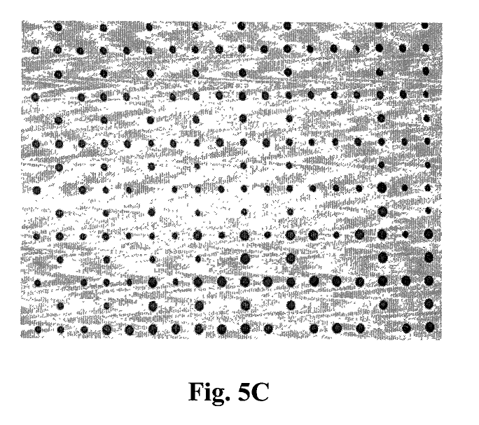

Although pin holes 12 may be formed in plate 11 by any reasonable method, it is contemplated that the methods disclosed herein will be particularly advantageous when pin receiving holes 12 are mechanically drilled in plate 11. However, it has been found that, after being drilled, such holes 12 are often at least partially obstructed by plate material that was not completely removed by the drilling process (see FIGS. 4A-4D). Such obstructions are generally undesirable because they tend to increase the force required to insert a test pin into a pin receiving hole and to prevent pins within the holes from making proper contact with a device under test. Such obstructions may be removed (as shown in FIGS. 5A-5C) by subjecting the plate to an etching process (see FIG. 2) after the holes 12 are drilled in plate 11, but prior to the insertion of pins 13.

It is contemplated that subjecting plate 11 to the etching process described herein will result in structural changes to plate 11. In particular, residues of the etch fluid are likely to be detectable in/on plate 11 after the etching process completes, and the surfaces (including the walls of the pin receiving holes) of plate 11 will likely have detectable surface characteristics caused by the etch process.

The test fixture of FIG. 1 may be manufactured by providing a support plate; forming pin receiving holes in the support plate; subjecting the support plate to an etch process; and inserting test pins into the pin receiving holes.

Referring to FIG. 3, subjecting the support plate to an etch process preferably comprises: submerging the support plate in a tank of heated etching fluid; rocking the support plate within the etching fluid for a period sufficient to remove any air trapped in the pin receiving holes and allow fluid to flow into the holes; submerging the support plate in a tank of rinsing fluid; and rocking the support plate within the rinsing fluid for a period sufficient to remove most of any etching fluid trapped in the pin receiving holes. It is currently preferred that the temperature of the etching fluid be at least 110 degrees Fahrenheit before and during the etching process.

It is currently preferred that the etching fluid be a combination of soft water, M glass etch, and sulfuric acid. In particular, a preferred etching fluid will have 55 gallons of soft water for every 30 pounds of M Glass etch and every 16 litters of sulfuric acid. However, alternative etching fluids may be used so long as they adequately remove the drilling residue from the test pin receiving holes 12. Using this etching fluid, the preferred temperature, and a plate made from G10 epoxy glass material, it is contemplated that submerging the support plate for 4 minutes in the etching fluid and two minutes in the rinsing fluid will sufficiently clean and polish holes 12 of plate 11.

At least some of the benefits of submitting plate 11 to an etching process can be seen by comparing the un-etched plates shown in FIGS. 4A-4D to the etched plates shown in FIGS. 5A-5C. In FIGS. 4A-4D it is clear that a number of the pin receiving holes are partially blocked as previously described, but that the obstructing material has been removed from the plates of FIGS. 5A-5C.

It is contemplated that submitting plate 11 to an etching process will significantly reduce the force required to insert a test pin into a test pin receiving hole and will result in a decrease in the time required to load pins 13 into plate 11. Reductions of 50% in pin insertion times have been experienced. Although the maximum force allowed for inserting pins 13 into holes 12 may very between applications, it is contemplated that etching plate 11 may advantageously reduce the force required to insert pins 13 into holes 12 sufficiently so that the pins can be dropped into all of the holes. However, in alternative embodiments the force of gravity may not be sufficient to pull a partially inserted pin completely into a hole for a 100 percent of the holes. In such embodiments, the percentage of holes in which the pins will simply drop into place may be only X percent where X is one of 50, 75, 90, and 95.

Thus, specific embodiments and applications of test fixtures and methods relating to the formation of test fixtures have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A test fixture comprising:
a pin support plate, the pin support plate comprising a plurality of test pin receiving holes, the holes having etched walls;
a plurality of pins, each pin positioned within a pin receiving hole.

2. The test fixture of claim 1 wherein the force of gravity is sufficient to cause greater than 50 percent of the plurality of pins to slide into or out of their pin receiving holes.

3. The test fixture of claim 1 wherein the force of gravity is sufficient to cause greater than 75 percent of the plurality of pins to slide into or out of their pin receiving holes.

4. The test fixture of claim 1 wherein the force of gravity is sufficient to cause greater than 90 percent of the plurality of pins to slide into or out of their pin receiving holes.

5. The test fixture of claim 1 wherein the force of gravity is sufficient to cause greater than 95 percent of the plurality of pins to slide into or out of their pin receiving holes.

6. A method of preparing a test fixture comprising a test pin support plate comprising:
providing a support plate;
forming pin receiving holes in the support plate;
subjecting the support plate to an etch process; and
inserting test pins into the pin receiving holes.

7. The method of claim 6 wherein the step of inserting test pins into the pin receiving holes comprises partially inserting the pins into the holes and then releasing them to allow gravity to pull them fully into the holes for at least 50 percent of the pin receiving holes.

8. The method of claim 7 wherein the step of subjecting the support plate to an etch process comprises:
submerging the support plate in a tank of heated etching fluid;
rocking the support plate within the etching fluid for a period sufficient to remove any air trapped in the pin receiving holes and allowing fluid to flow into and through the holes;
submerging the support plate in a tank of rinsing fluid; and
rocking the support plate within the rinsing fluid for a period sufficient to remove most of any etching fluid trapped in the pin receiving holes.

9. The method of claim 8 wherein the etching fluid is a combination of soft water, M glass etch, and sulfuric acid.

10. The method of claim 9 wherein the etching fluid comprises 55 gallons of soft water for every 30 pounds of M. Glass etch and every 16 litters of sulfuric acid.

11. The method of claim 10 wherein the etching fluid is heated to a temperature of at least 110 degrees Fahrenheit before and during submersion of the plate in the etching fluid.
